(19) United States
(12) Patent Application Publication
(10) Pub. No.: US 2016/0118269 A1
(43) Pub. Date: Apr. 28, 2016

(54) GATE SLOT OVERETCH CONTROL

(71) Applicant: Texas Instruments Incorporated, Dallas, TX (US)

(72) Inventors: EBENEZER ESHUN, FRISCO, TX (US); BRIAN K. KIRKPATRICK, ALLEN, TX (US)

(21) Appl. No.: 14/521,157

(22) Filed: Oct. 22, 2014

(51) Int. Cl. H01L 21/3213; H01J 37/32; H01L 21/285; H01L 21/67; H01L 21/28; H01L 21/768

(52) U.S. Cl. CPC H01L 21/32137; H01L 21/28035; H01L 21/768; H01L 21/28525; H01L 21/67069; H01J 37/32963

(57) ABSTRACT

A method of gate slot etching for a memory device. Gate electrode lines are formed from a layer of gate electrode material oriented in a first direction using a first exposure and first etch process. Slots are formed oriented in a second direction orthogonal to the first direction in the gate electrode lines using a second exposure and second etch process, where the second etch process includes a bounded overetch amount (BOA) that sets a physical slot width that is bounded (bounded slot width). The BOA is determined by actual electrical test data obtained from the memory device including identifying a lower overetch amount which is <the BOA from a first electrical failure mode associated with the physical slot width being too short, and identifying an upper overetch amount which is >the BOA from a second electrical failure mode associated with the physical slot width being too long.

### FIELD

Disclosed embodiments relate to gate electrode etching for semiconductor devices.

### BACKGROUND

Gate electrode definition is an important processing step for complementary metal-oxide semiconductor (CMOS) devices. However, for any photolithographic technique, there is a minimum feature size that can be printed. This minimum feature size is defined not only by the size of the feature to be printed, but also by proximity for what is around the feature. In the case of gate lines, small critical dimensions (CDs) tend to merge ends of some of the adjacent gate lines when using conventional single pattern lithography processes.

Multiple pattern lithography including double expose and double etch involves a sequence of at least two separate exposures and etchings of independent patterns into the same layer. Double expose, double etch is known for achieving smaller gate CDs that are not otherwise possible to be formed reliably using conventional single pattern lithography.

### SUMMARY

This Summary is provided to introduce a brief selection of disclosed concepts in a simplified form that are further described below in the Detailed Description including the drawings provided. This Summary is not intended to limit the claimed subject matter's scope.

Disclosed embodiments relate to multiple pattern lithography for forming gate electrodes including double expose, double etch gate electrode formation processes for metal oxide semiconductor (MOS) devices in memory cells of a memory device of an integrated circuit (IC) having gate slots (missing gate electrode line segments). Disclosed embodiments recognize when the slot width of the gate slot is reduced beyond a certain level, such as to 32 nm to 38 nm, some of the cells in the memory will have electrical failures including line ends shorted across the intended slot resulting in failures.

In one arrangement, gate slots oriented in a second direction orthogonal to a first direction in the gate electrode lines formed in a first pattern process are formed using at least a second exposure and second etch process. The second etch process includes a bounded overetch amount (BOA) that sets a physical slot width that is bounded (bounded slot width). The BOA is determined by actual electrical test data obtained from the memory device when completed including identifying a lower overetch amount which is less than (<) the BOA from a first electrical failure mode associated with the physical slot width being too short, and identifying an upper overetch amount which is greater than (>) the BOA from a second electrical failure mode different from the first electrical failure mode associated with the physical slot width being too long.

### BRIEF DESCRIPTION OF THE DRAWINGS

Reference will now be made to the accompanying drawings, which are not necessarily drawn to scale, wherein:

FIG. 1 is a flow chart that shows steps in an example method of gate slot etching for an integrated circuit (IC) including a memory device, according to an example embodiment.

FIG. 2 is a block diagram of an etch system including overetch control for gate slot etching of an IC including a memory device, according to an example embodiment.

FIGS. 3A-3C are scanned scanning electron microscope (SEM) images of a 6 transistor (6T) static random access memory (SRAM) cell after gate polysilicon etch for different degrees of OE showing from an overetch of 200 Å, 250 Å and 300 Å, respectively.

FIG. 4 is a plot of data retention (DRET) failure (%) rates for various gate polysilicon OE amounts of 150 Å, 200 Å, 250 Å, and 300 Å for a completed IC having a memory device.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

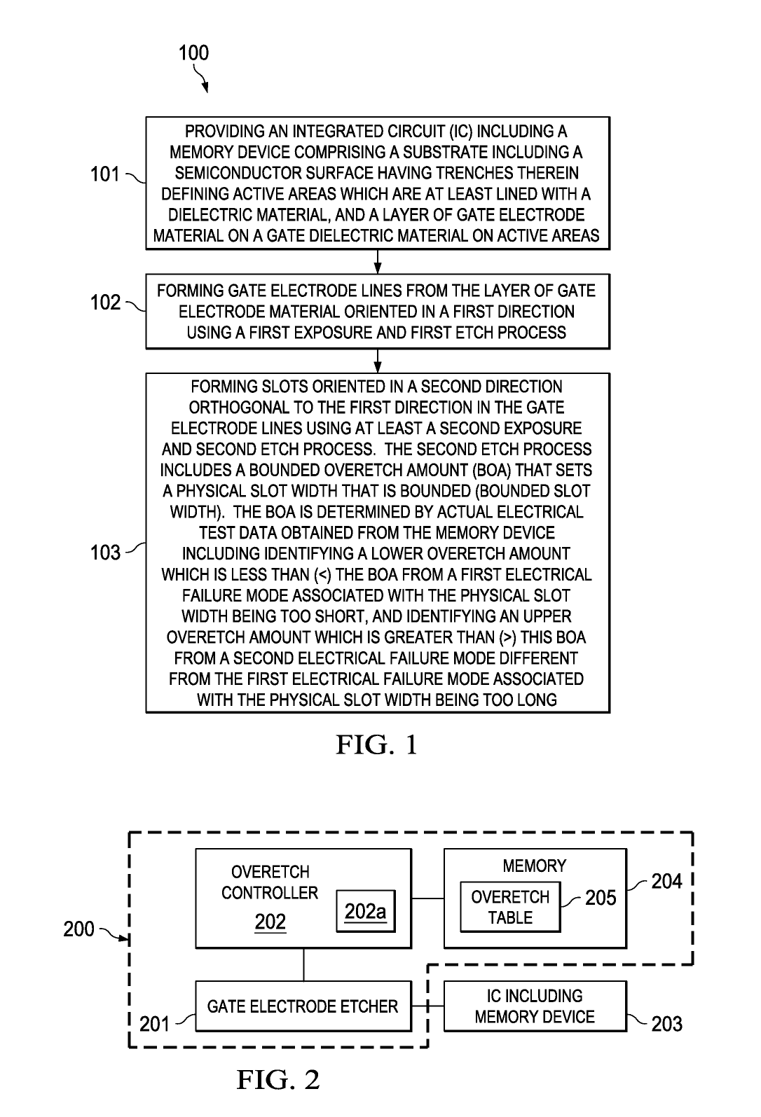

FIG. 1 is a flow chart that shows steps in an example method 100 of gate slot etching for an IC including a memory device, according to an example embodiment. The IC generally comprises a complementary metal-oxide semiconductor (CMOS) device having both NMOS transistors and PMOS transistors. The memory device can comprise a read-only-memory (ROM) such as a flash electrically erasable programmable read-only memory (EEPROM), a random access memory (RAM) such as a static RAM (SRAM), magnetoresistive random-access memory (MRAM), dynamic RAM (DRAM), or other memory device. The IC can be a standalone memory device or an IC device having an embedded memory.

Step 101 comprise providing a substrate (e.g., a wafer) including a semiconductor surface having trenches therein defining active areas which are at least lined with a dielectric material, and a layer of gate electrode material on a gate dielectric material on active areas. The trenches can comprise shallow trench isolation (STI) or other isolation. The substrate and/or semiconductor surface can comprise silicon, silicon-germanium, or other semiconductor material. One particular arrangement is a silicon/germanium (SiGe) semiconductor surface on a silicon substrate. The gate dielectric material can comprise a high-k dielectric material. In one particular embodiment the gate electrode material comprise polysilicon. In other embodiments the gate electrode material comprises at least one metal.

Step 102 comprises forming gate electrode lines from the layer of gate electrode material oriented in a first direction using a first exposure and first etch process. The lithography tool used can comprise a 193 nm immersion lithography tool.

Step 103 comprises forming gate slots oriented in a second direction orthogonal to the first direction in the gate electrode lines using at least a second exposure and second etch process. The second etch process includes a BOA that sets a physical slot width that is bounded (bounded slot width). The BOA is determined by actual electrical test data obtained from the memory device once completed including identifying a lower overetch amount which is less than (<) the BOA from a first electrical failure mode associated with the physical slot width being too short, and identifying an upper overetch amount which is greater than (>) the BOA from a second electrical failure mode different from the first electrical failure mode associated with the physical slot width being too long. The electrical failures are generally not ascertainable from imaging the IC including using scanning electron microscopes (SEMs).

For example, applied to polysilicon gate SRAMs, the first electrical failure mode associated with the physical slot width being too short can be when the slot is intended to separate ends of a polysilicon gate line, where residual polysilicon “stringers” can remain between adjacent polysilicon line ends if the OE amount is insufficient to open enough space across the full array of memory cells. This can cause storage node-to-storage node leakage failures. The second electrical failure mode associated with the physical slot width being too long can be when the OE is too much, this can lead to exposing the STI divot region/active edge which can result in subsequent processing causing power supply (Vdd) to ground leakage including shorting that results in power up failures (gate electrode to S/D leakage or shorts).

The BOA will generally be specific for each memory device (e.g., 6T SRAM, 8T SRAM, DRAM, MRAM), whether embedded memory or standalone memory, and also specific each node (node meaning 28 nm, 20 nm, 14 nm, . . . ). The parameters for setting the BOA can include:

a. Gate electrode area exposed to the slot etch;
b. Etch bias between the memory array and logic;
c. Gate electrode pitch;
d. Final slot dimension relative to electrical fails (i.e. design margin); and
e. Across wafer uniformity differences driven by macro density changes in the chip design.

Although feedback data can be used during the second etch process, while feedback data is generally necessary, such feedback data was found to be insufficient to stop the second etch at the right point to avoid both the first electrical failure mode associated with the physical slot width being too short and the second electrical failure mode associated with the physical slot width being too long.

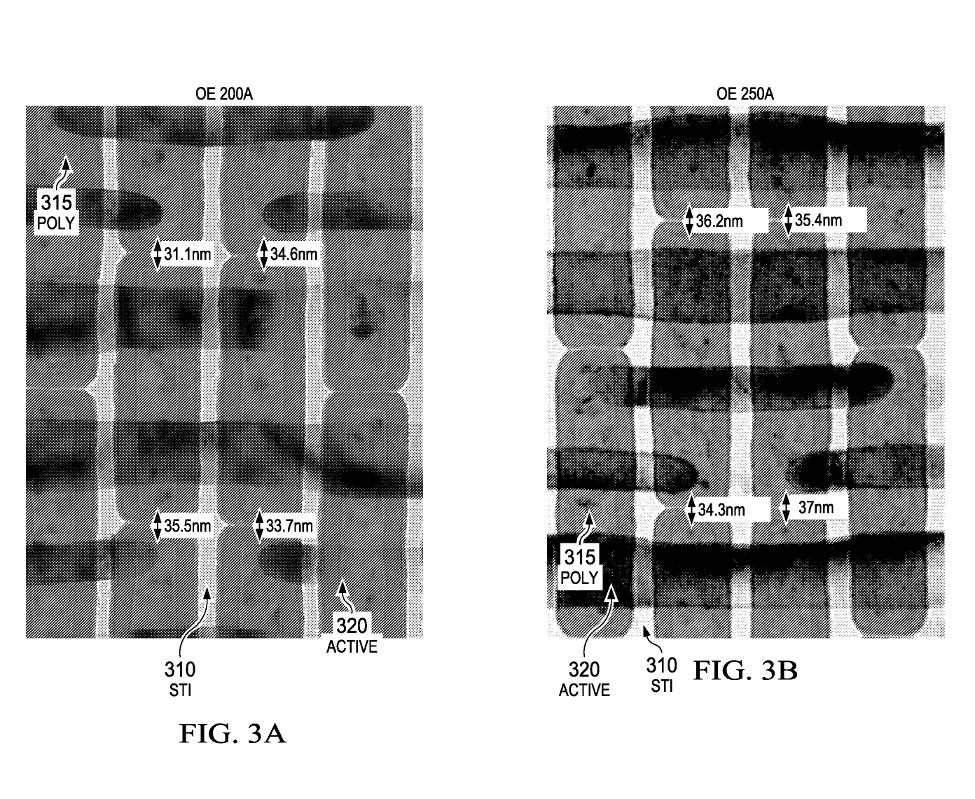

FIG. 2 is a block diagram of an etch system including overetch control (system) 200 for gate slot etching of an IC including a memory device 203, according to an example embodiment. System 200 includes a gate electrode etcher 201 configured to perform etching with overetching for ICs including a memory device 203 on a substrate (e.g., wafer) having a semiconductor surface including trenches therein defining active areas which are at least lined with a dielectric material, and a layer of gate electrode material on a gate dielectric material on active areas having gate electrode lines comprising the gate electrode material oriented in a first direction placed in the gate electrode etcher. The gate electrode etcher 201 can comprise a plasma etcher. An overetch controller 202 comprises a processor 202a having an associated memory 204 including an overetch table 205 coupled to the gate electrode etcher 201 configured for a gate slot etch processing to form slots in the gate electrode lines oriented in a second direction orthogonal to the first direction provided in an earlier first patterning process.

The slot etch process utilizes a BOA from the overetch table 205 that sets a physical slot width that is bounded (bounded slot width). The BOA is determined by actual electrical test data obtained from the memory device including identifying a lower overetch amount which is less than (<) the BOA from a first electrical failure mode associated with the physical slot width being too short, and identifying an upper overetch amount which is greater than (>) the BOA from a second electrical failure mode different from the first electrical failure mode associated with the physical slot width being too long. The overetch controller 202 initiates and halts operation of the gate electrode etcher 201 during the etch and overetch processing.

### Examples

Disclosed embodiments are further illustrated by the following specific Examples, which should not be construed as limiting the scope or content of this Disclosure in any way.

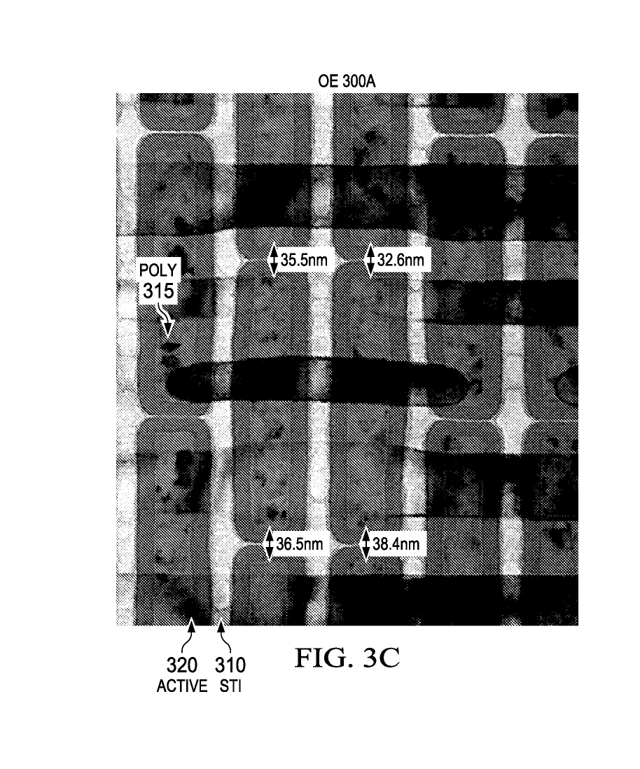

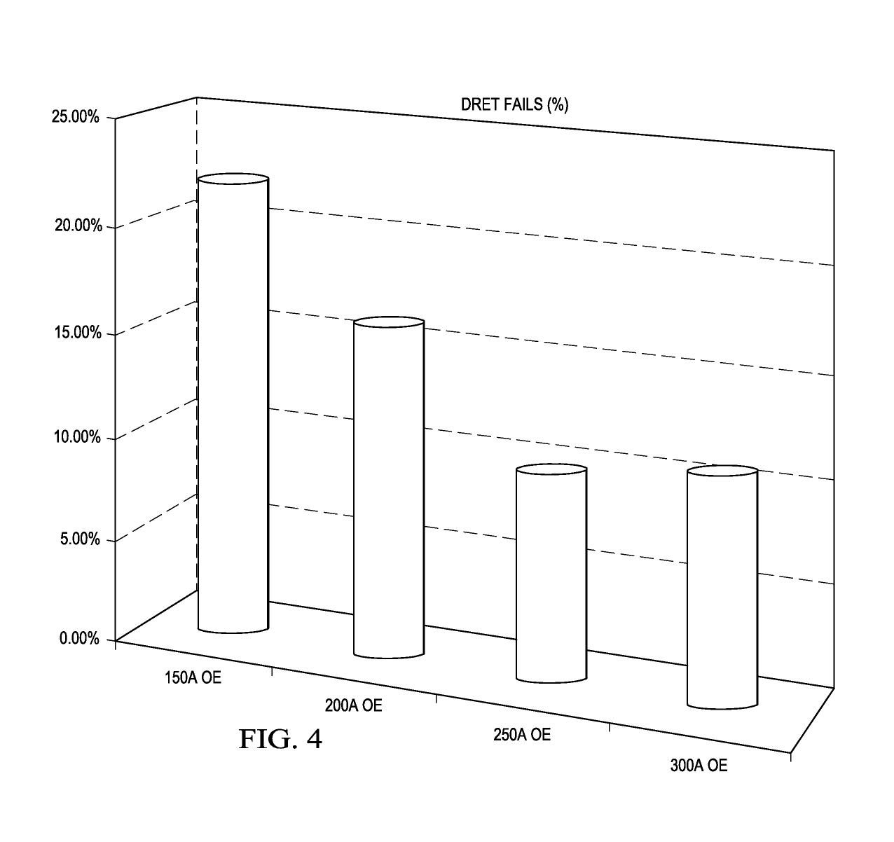

FIGS. 3A-3C are scanned SEM images of a 6T SRAM cell after gate polysilicon etch for different degrees of OE showing an overetch of 200 Å, 250 Å and 300 Å, respectively. The gate slots widths are indicated by the double arrows shown. STI is shown as 310, polysilicon lines (poly) as 315 and active area (active) as 320. No defects can be seen in the scanned images including no evidence of residual polysilicon stringers or any exposed STI divot region/active edges. However, as described below in FIG. 4, the 200 Å and 300 Å OE were both found to result in a higher level of electrical failures for completed ICs having memory devices as compared to the 250 A OE with results shown in FIG. 3B.

FIG. 4 is a plot of DRET failure (%) rates across an SRAM for various gate polysilicon OE amounts of 150 Å, 200 Å, 250 Å, and 300 Å for completed ICs having memory devices. The 250 A OE is shown providing the lowest % DRET fails, with higher DRET failure rates for less OE (200 Å) and more OE (300 Å).

Disclosed embodiments can be used to form semiconductor die that may be integrated into a variety of assembly flows to form a variety of different devices and related products. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, Insulated Gate Bipolar Transistor (IGBT), CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

1. A method, comprising:
performing an electrical test on a first integrated circuit having first gate electrode lines aligned in a first direction and separated by first slots aligned in a second direction perpendicular to the first direction, the electrical test defining: a first failure mode related to a first current leakage between the gate electrode lines, and a second failure mode related to a second current leakage within an active region of the first integrated circuit;
determining a lower overetch amount associated with the first failure mode;
determining an upper overetch amount associated with the second failure mode; and
overetching a second slot between second gate electrode lines of a second integrated circuit according to an overetch amount bounded by the lower overetch amount and the upper overetch amount.

2.-10. (canceled)

11. A method, comprising:
performing an electrical test on a first integrated circuit having first gate electrode lines aligned in a first direction and separated by first slots aligned in a second direction perpendicular to the first direction, the electrical test defining a failure mode related to a current leakage between the gate electrode lines;
determining a lower overetch amount associated with the failure mode; and
overetching a second slot between second gate electrode lines of a second integrated circuit according to an overetch amount bounded by the lower overetch amount.

12. A method, comprising:
performing an electrical test on a first integrated circuit having first gate electrode lines aligned in a first direction and separated by first slots aligned in a second direction perpendicular to the first direction, the electrical test defining a failure mode related to a current leakage within an active region of the first integrated circuit;
determining an upper overetch amount associated with the failure mode; and
overetching a second slot between second gate electrode lines of a second integrated circuit according to an overetch amount bounded by the upper overetch amount.
